(19) United States
(12) Patent Application Publication
(10) Pub. No.: US 2026/0110084 A1
(43) Pub. Date: Apr. 23, 2026

(54) INJECTION GAS ACTIVATION FOR PROCESSING CHAMBERS, AND RELATED CHAMBER KITS, APPARATUS, AND METHODS

(71) Applicant: Applied Materials, Inc., Santa Clara, CA (US)

(72) Inventor: Aniketnitin PATIL, San Jose, CA (US)

(21) Appl. No.: 18/922,005

(22) Filed: Oct. 21, 2024

(51) Int. Cl. C23C 16/452

(52) U.S. Cl. CPC C23C 16/452

(57) ABSTRACT

The present disclosure relates to injection gas activation, such as for low-temperature processing, and related chamber kits, methods, and processing chambers. In one or more embodiments, a processing chamber includes a chamber body at least partially defining an internal volume. The chamber body includes one or more gas inlet openings. The processing chamber includes a substrate support disposed in the internal volume, one or more heat sources, and a liner disposed at least partially about the internal volume. The processing chamber includes an absorptive mass supported at least partially by the liner between the one or more gas inlet openings and the substrate support.

### BACKGROUND

### Field

The present disclosure relates to injection gas activation, such as for low-temperature processing, and related chamber kits, methods, and processing chambers.

### Description of the Related Art

Semiconductor substrates are processed for a wide variety of applications, including the fabrication of integrated devices and microdevices. One method of processing substrates includes depositing a material, such as a semiconductor material or a conductive material, on an upper surface of the substrate. For example, epitaxy is one deposition process that deposit films of various materials on a surface of a substrate in a processing chamber. During processing, various parameters can affect the uniformity of material deposited on the substrate.

Operations (such as epitaxial deposition operations) involve one or more processing gases to be heated in order to be activated (such as cracked). Relatively higher processing temperatures can involve unintended dopant diffusion and/or hindered device performance. In addition, high processing temperatures can damage already structures formed on the substrate. However, it can be difficult to activate processing gases at relatively lower temperatures. Moreover, different gases can involve different activation temperatures. Additionally, it can be difficult to adjust heating without adding complexity to chamber designs and electrical supply lines.

Therefore, a need exists for improved apparatuses and methods in semiconductor processing.

### SUMMARY

The present disclosure relates to injection gas activation, such as for low-temperature processing, and related chamber kits, methods, and processing chambers.

In one or more embodiments, a processing chamber includes a chamber body at least partially defining an internal volume. The chamber body includes one or more gas inlet openings. The processing chamber includes a substrate support disposed in the internal volume, one or more heat sources, and a liner disposed at least partially about the internal volume. The processing chamber includes an absorptive mass supported at least partially by the liner between the one or more gas inlet openings and the substrate support.

In one or more embodiments, a chamber kit includes a liner that includes a first curved body and an opening formed in an outer face of the first curved body, and an absorptive mass that includes a second curved body sized and shaped for disposition at least partially in the opening of the liner. The absorptive mass is formed of an opaque material.

In one or more embodiments, a method of substrate processing includes heating an absorptive mass disposed in a gas inlet path of a processing chamber. The heating includes emitting an electromagnetic radiation to the absorptive mass such that the absorptive mass absorbs the electromagnetic radiation. The method includes heating a substrate in the processing chamber, flowing one or more process gases over the absorptive mass to pre-heat the one or more process gases, and flowing the one or more process gases over the substrate to process the substrate.

For visual clarity purposes surface shading and/or hatching is omitted from parts of certain figures. For example, in FIGS. 2 and 3 surface shading is omitted from the substrate 102, the first shoulder 1033, and the second shoulder 1034.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a partial schematic side cross-sectional view of a processing chamber, according to one or more embodiments.

FIG. 1B is an enlarged schematic view of the processing chamber shown in FIG. 1A, according to one or more embodiments.

FIG. 2 is a schematic partial top view of the processing chamber, according to one or more embodiments.

FIG. 3 is a schematic partial top view of the processing chamber, according to one or more embodiments.

FIG. 4 is a schematic front view of an absorptive mass according to one or more embodiments.

FIG. 5 is a schematic front view of an absorptive mass according to one or more embodiments.

FIG. 6 is a schematic top view of the reflector shown in FIG. 1A, according to one or more embodiments.

FIG. 7 is a schematic perspective view of a linear lamp for use within the processing chamber of FIG. 1, according to one or more embodiments.

FIG. 8 is a schematic perspective view of a curved lamp for use within the processing chamber of FIG. 1, according to one or more embodiments.

FIG. 9 is a schematic block diagram view of a method of substrate processing, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to injection gas activation, such as for low-temperature processing, and related chamber kits, methods, and processing chambers. Absorptive mass and liner arrangements for gas activation are also disclosure. In one or more embodiments, an absorptive mass is used to pre-heat process gases for low-temperature processing (such as low temperature deposition (e.g., epitaxy), pre-cleaning, etching, and/or chamber cleaning). An absorptive mass can be disposed in a gas inlet path such that one or more process gases flow over the absorptive mass. The absorptive mass can be supported by a liner, such as a lower liner.

The disclosure contemplates that terms such as “couples,” “coupling,” “couple,” and “coupled” may include but are not limited to embedding, bonding, welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

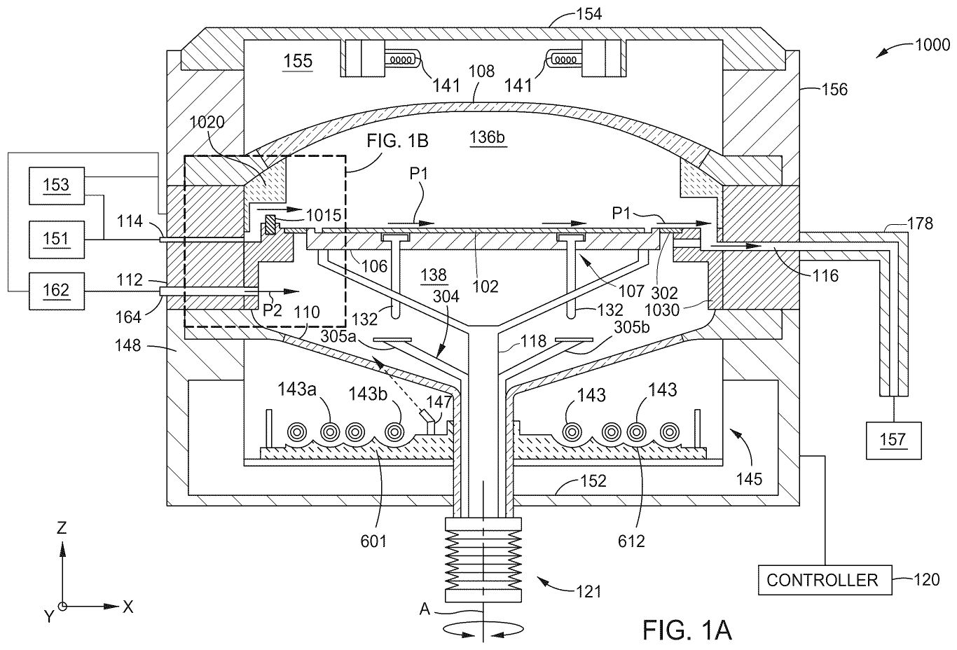

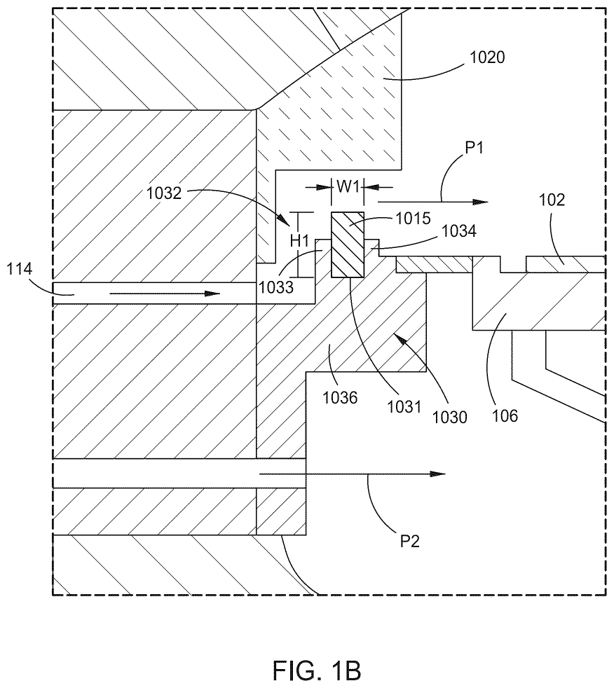

FIG. 1A is a partial schematic side cross-sectional view of a processing chamber 1000, according to one or more embodiments. The processing chamber 1000 is a deposition chamber. In one or more embodiments, the processing chamber 1000 is an epitaxial deposition chamber. In one or more embodiments, the processing chamber 1000 is utilized to grow an epitaxial film on a substrate 102. The processing chamber 1000 creates a cross-flow of precursors across a top surface of the substrate 102. The processing chamber 1000 is shown in a processing condition in FIG. 1.

The processing chamber 1000 includes an upper body 156, a lower body 148 disposed below the upper body 156, a flow module 112 disposed between the upper body 156 and the lower body 148. The upper body 156, the flow module 112, and the lower body 148 form a chamber body. Disposed within the chamber body is a substrate support 106, an upper plate 108 (such as an upper window and/or an upper dome), a lower plate 110 (such as a lower window and/or a lower dome), a plurality of upper heat sources 141, and a plurality of lower heat sources 143. The present disclosure contemplates that the upper plate 108 and/or the lower plate 110 can be in the shape of a dome or can be in another shape, such as flat, concave, or another contour.

As shown, a controller 120 is in communication with the processing chamber 1000 and is used to control processes and methods, such as the operations of the methods described herein. The present disclosure contemplates that each of the heat sources described herein can include one or more of: lamp(s), resistive heater(s), diodes (such as light emitting diode(s) (LEDs)), and/or laser source(s) (such as laser diodes and/or vertical-cavity surface emitting lasers (VCSLs)). The one or more heat sources can be configured to emit electromagnetic radiation, such as infrared radiation or ultraviolet radiation. In one or more embodiments, the one or more heat sources are configured to emit laser light. The present disclosure contemplates that other heat sources can be used.

The substrate support 106 is disposed between the upper plate 108 and the lower plate 110. The substrate support 106 includes a support face that supports the substrate 102. The plurality of upper heat sources 141 are disposed between the upper window and a lid 154. The plurality of upper heat sources 141 form a portion of the upper heat source module 155. The lid 154 may include a plurality of sensors disposed therein or thereon for measuring the temperature within the processing chamber 1000. The plurality of lower heat sources 143 are disposed between the lower plate 110 and a floor 152. The plurality of lower heat sources 143 form a portion of a lower heat source module 145. In one or more embodiments, the upper plate 108 is an upper dome and is formed of an energy transmissive material, such as quartz. In one or more embodiments, the lower plate 110 is a lower dome and is formed of an energy transmissive material, such as quartz. A pre-heat ring 302 is disposed outwardly of the substrate support 106. A stop 304 includes a plurality of arms 305a, 305b that each include a lift pin stop on which at least one of the lift pins 132 can rest when the substrate support 106 is lowered (e.g., lowered from a process position to a transfer position).

The internal volume has the substrate support 106 disposed therein. The substrate support 106 includes a top surface on which the substrate 102 is disposed. The substrate support 106 is attached to a shaft 118. The shaft 118 is connected to a motion assembly 121. The motion assembly 121 includes one or more actuators and/or adjustment devices that provide movement and/or adjustment for the shaft 118 and/or the substrate support 106.

The substrate support 106 may include lift pin perforations 107 disposed therein. The lift pin perforations 107 are sized to accommodate a lift pin 132 for lifting of the substrate 102 from the substrate support 106 either before or after a deposition process is performed.

The chamber body includes one or more liners disposed at least partially about the internal volume, such as a first liner 1020 (e.g., an upper liner) and a second liner 1030 (e.g., a lower liner). The second liner 1030 can be disposed below the first liner 1020. The pre-heat ring 302 is supported on a ledge of the second liner 1030. The chamber body includes one or more gas inlet openings 114 through which the one or more process gases P1 are supplied into the internal volume of the processing chamber 1000.

An absorptive mass 1015 is supported at least partially by at least one of the liners 1020, 1030 between the one or more gas inlet openings 114 and the substrate support 106. In one or more embodiments, the absorptive mass 1015 is supported at least partially by the second liner 1030. The processing chamber 1000 includes a reflector 601 that includes one or more recessed surfaces 612. The lower heat sources 143 can be disposed respectively in grooves that define the one or more recessed surfaces 612. The one or more recessed surfaces 612 can reflect energy (such as electromagnetic radiation) that is emitted by the heat sources 143.

At least part of reflector(s) such as the reflector 601 can reflect the energy toward the absorptive mass 1015. For example, at least one recessed surface 612 corresponding to a zone of one or more of the heat sources 141, 143 can reflect the energy toward the absorptive mass 1015. One or more first zones (such as zone 143a) of the plurality of heat sources 141, 143 emit the energy to the absorptive mass 1015, and one or more second zones (such as zone 143b) of the plurality of heat sources 141, 143) emit energy to the substrate 102. The one or more first zones can be used to heat the absorptive mass 1015 in a dedicated manner, or the one or more first zones can also emit energy to the substrate 102 for substrate heating. In one or more embodiments, the one or more first zones (such as zone 143a) are disposed radially outwardly of at least one of the one or more second zones (such as zone 143b). As described, at least one zone of the lower heat sources 143 can emit energy to the absorptive mass 1015. The present disclosure contemplates that at least one zone of the upper heat sources 141 can emit energy to the absorptive mass 1015. The present disclosure contemplates that a dedicated heat source 147 can be used to heat the absorptive mass 1015. The dedicated heat source 147 can include for example a lamp, a laser source, a diode, or another heat source as described herein. In one or more embodiments, the transparent section of the second liner 1030 spans at least a line of sight that extends between the absorptive mass 1015 and the one or more heat sources (such as zone 143a) that are used to heat the absorptive mass 1015.

The one or more gas inlet openings 114 are fluidly connected between the processing volume 136 of the internal volume and one or more process gas sources 151 and one or more cleaning gas sources 153. The purge gas inlet(s) 164 are fluidly connected to one or more purge gas sources 162. The one or more gas exhaust outlets 116 are fluidly connected to an exhaust pump 157. One or more process gases supplied using the one or more process gas sources 151 can include one or more reactive gases (such as one or more of silicon-containing, phosphorus-containing, and/or germanium-containing gases, and/or one or more carrier gases (such as one or more of nitrogen (N2) and/or hydrogen (H2)), and/or one or more etchant gases (such as one or more of hydrogen and/or chlorine (such as hydrochloric acid (HCl)). One or more purge gases supplied using the one or more purge gas sources 162 can include one or more inert gases (such as one or more of argon (Ar), helium (He), and/or nitrogen (N2)). One or more cleaning gases and/or etching gases supplied using the one or more cleaning gas sources 153 can include one or more of hydrogen and/or chlorine (such as hydrochloric acid (HCl)). In one or more embodiments, the one or more process gases include silicon hydrides (such as one or more silanes and/or one or more chlorinated silanes), germanium (such as germane (GeH4)), boron (such as diborane (B2H6)), and/or phospine (PH3).

The one or more gas exhaust outlets 116 are further connected to or include an exhaust system 178. The exhaust system 178 fluidly connects the one or more gas exhaust outlets 116 and the exhaust pump 157. The exhaust system 178 can assist in the controlled deposition of a layer on the substrate 102. The exhaust system 178 is disposed on an opposite side of the processing chamber 1000 relative to the flow module 112.

During a deposition operation (e.g., an epitaxial growth operation), the one or more process gases P1 flow through the one or more gas inlet openings 114 and into the processing volume 136 to flow horizontally over the substrate support 106 and the substrate 102 and to the one or more gas exhaust outlets 116. The one or more purge gases P2 are supplied from one or more purge gas sources 162 to the purge volume 138 through one or more purge gas inlets 164. The one or more purge gases P2 flow simultaneously with the flowing of the one or more process gases P1. The one or more process gases P1 are exhausted through exhaust gaps between the first liner 1020 and the second liner 1030, and through the one or more gas exhaust outlets 116. The one or more purge gases P2 are exhausted through the same exhaust gaps between the first liner 1020 and the second liner 1030, and through the same one or more gas exhaust outlets 116 as the one or more process gases P1. The present disclosure contemplates that that one or more purge gases P2 can be separately exhausted through one or more second gas exhaust outlets that are separate from the one or more gas exhaust outlets 116.

FIG. 1B is an enlarged schematic view of the processing chamber 10000 shown in FIG. 1A, according to one or more embodiments.

The second liner 1030 includes an opening 1031 (such as a recess) formed in an outer face 1032 of the liner 1030. The absorptive mass 1015 is sized and shaped for disposition at least partially in the opening 1031 of the second liner 1030. The second liner 1030 includes a first shoulder 1033 on a first side of the opening 1031 and a second shoulder 1034 on a second side of the opening 1031. The absorptive mass 1015 rests on a recessed surface between the two shoulders 1033, 1034 of the second liner 1030. The absorptive mass 1015 has a cross-section having a width W1 that is lesser than a height H1. The height H1 of the absorptive mass 1015 is larger than respective heights of the first shoulder 1033 and the second shoulder 1034. The width W1 is a ratio of the height H1, and the ratio is 0.60 or less, such as 0.50 or less. In one or more embodiments, the width W1 is 5.0 mm or less, such as 3.0 mm or less. In one or more embodiments, the height H1 is 7.0 mm or larger, such as 10.0 mm or larger. In one or more embodiments, the cross-section of the absorptive mass 1015 is rectangular in shape, and can include edges that are sharp, tapered, or rounded.

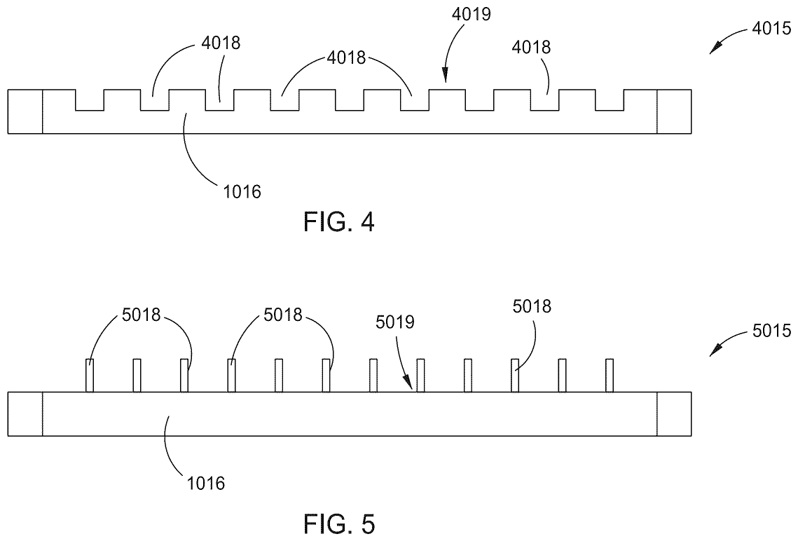

Other shapes are contemplated for the cross-section of the absorptive mass 1015, such as a square, a circle, an oval, a triangle, a star, a polygon (for example a pentagon, a hexagon, an octagon, or another polygon), an “X,” a “V,” a “U,” or another shape. As described in relation to FIGS. 4 and 5, the absorptive mass 1015 can have a variety of features (such as grooves, recesses, extensions, and/or fins) to facilitate increased surface area for gas activation while facilitating beneficial gas flow (such as laminar flow) over the absorptive mass 1015.

Energy (such as electromagnetic radiation) is directed towards the absorptive mass 1015 to heat the absorptive mass 1015 during processing. At least a section 1036 of the second liner 1030 is formed of a transparent material, such as a clear quartz, to allow the energy to pass through the second liner 1030 and be absorbed by the absorptive mass 1015. The transparent section 1036 of the second liner 1030 supports the absorptive mass 1015.

The absorptive mass 1051 is formed of an opaque material configured to absorb the energy. The opaque material has thermal properties that facilitate quickly and efficiently heating the absorptive mass 1015, and emitting the heat to activate gases (such as the one or more process gases P1). During processing, the one or more process gases P1 flow over the absorptive mass 1015 to activate the one or more process gases. The opaque material has an emissivity that is greater than or equal to 0.45 at a processing temperature, such as 0.75 or higher at the processing temperature. In one or more embodiments, the emissivity of the opaque material is within a range of 0.45 to 0.9, such as 0.75 to 0.9, or higher, at the processing temperature. In one or more embodiments, the emissivity is within a range of 0.75 to 0.85, such as about 0.80. In one or more embodiments, the emissivity is 0.80 or higher, such as 0.90 or higher, at the processing temperature. For example, the absorptive mass 1015 can be a black body. Other emissivity values are contemplated. The processing temperature can be, for example, 250 degrees Celsius, 400 degrees Celsius, 600 degrees Celsius or 1,000 degrees Celsius. Other processing temperatures are contemplated.

The opaque material has a thermal conductivity that is less than 100.0 W/m-K, such as less than 10.0 W/m-K, at a processing temperature. In one or more embodiments, the thermal conductivity of the opaque material is less than 5.0 W/m-K at the processing temperature, such as less than 3.0 W/m-K at the processing temperature. In one or more embodiments, the thermal conductivity of the opaque material is about 1.5 W/m-K at the processing temperature. Other thermal conductivity values are contemplated.

The opaque material includes one or more of silicon carbide (SiC), graphite coated with SiC, graphite coated with opaque quartz, and/or opaque quartz (such as black quartz, grey quartz, and/or white quartz). In one or more embodiments, the absorptive mass 1015 is formed of SiC. In one or more embodiments, the SiC is pure SiC (e.g., having an atomic percentage of at least 99% for silicon and carbon) formed using chemical vapor deposition (CVD). It is believed that the pure SiC is resistant to process gases (e.g., corrosion resistant) and facilitates high absorption and emissivity, and facilitates increasing a surface area of the absorptive mass 1015. The present disclosure contemplates that a variety of atomic structures may be used for the SiC, such as 3C, 4H, 6H, or another atomic structure.

During a processing operation (such as deposition, etching, cleaning, and/or pre-cleaning, for example) at least one of the heat sources 141, 143 and/or other heat source(s) can emit energy toward the absorptive mass 1015 to be absorbed by the absorptive mass 1015.

The one or more process gases P1 flow over the absorptive mass 1015 to be pre-heated and activated by heat emitted by the absorptive mass 1015. The one or more process gases P1 then flow over the pre-heat ring 302, the substrate support 106, and the substrate 102. A first temperature of the one of more process gases P1 before the one or more process gases P1 flow over the absorptive mass 1015 is lower than a second temperature of the one or more process gases P1 after the one or more process gases P1 flow over the absorptive mass 1015.

The subject matter herein is described in relation to the processing chamber 1000. The present disclosure contemplates that the subject matter (such as the absorptive mass 1015 and the liner 1030) can be used in relation to other processing chamber architectures and chamber designs.

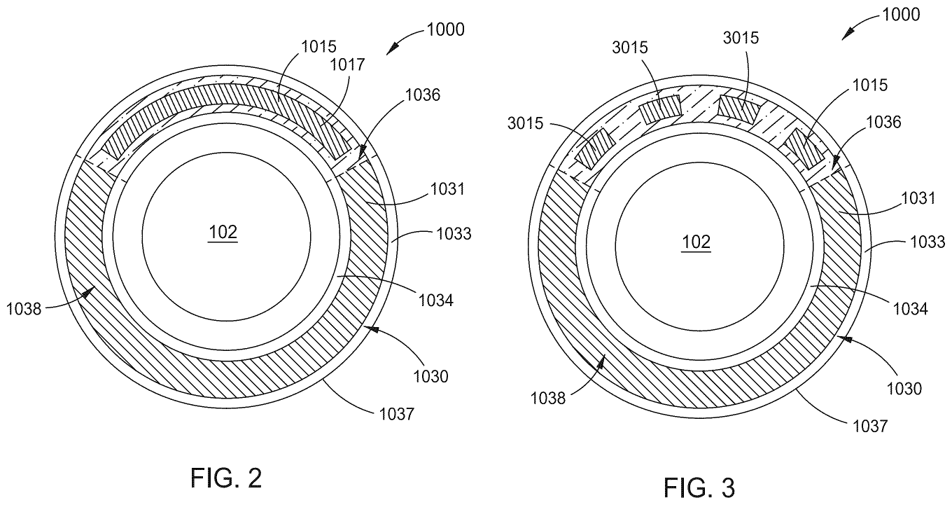

FIG. 2 is a schematic partial top view of the processing chamber 1000, according to one or more embodiments.

The second liner 1030 includes a first curved body 1037 that includes the aspects, features, components, operations, and properties (such as the opening 1031) described for the second liner 1030. The absorptive mass 1015 includes a second curved body 1017 that includes the aspects, features, components, operations, and properties (such as the height H1, width W1, and cross-section) described for the absorptive mass 1015. The first curved body 1037 of the second liner 1030 includes the transparent section 1036 and an opaque section 1038 disposed azimuthally outside of the transparent section 1036. The opaque section 1038 is formed of an opaque material. In one or more embodiments, the opaque material of the opaque section 1038 includes opaque quartz, such as white quartz.

FIG. 3 is a schematic partial top view of the processing chamber 1000, according to one or more embodiments.

In the implementation shown in FIG. 3, a plurality of absorptive masses 3015 are supported in the opening 1031 of the second liner 1030. The absorptive masses 3015 includes one or more aspects, features, components, operations, and/or properties of the absorptive mass 1015. The absorptive masses 3015 respectively include a curved body and are azimuthally spaced from each other.

FIG. 4 is a schematic front view of an absorptive mass 4015 according to one or more embodiments. The absorptive mass 4015 includes one or more aspects, features, components, operations, and/or properties of the absorptive mass 1015. The absorptive mass 4015 can be used in place of the absorptive mass 1015 or in place of the respective absorptive masses 3015.

In the implementation shown in FIG. 4, the second curved body 1016 of the absorptive mass 4015 includes a plurality of openings 4018 formed in an outer face 4019 of the second curved body 1016. The plurality of openings 4018 are spaced (e.g., azimuthally spaced) from each other along a length (such as a curved length) of the second curved body 1016.

FIG. 5 is a schematic front view of an absorptive mass 5015 according to one or more embodiments. The absorptive mass 5015 includes one or more aspects, features, components, operations, and/or properties of the absorptive mass 1015. The absorptive mass 5015 can be used in place of the absorptive mass 1015 or in place of the respective absorptive masses 3015.

In the implementation shown in FIG. 5, the second curved body 1016 of the absorptive mass 5015 includes a plurality of extensions 5018 extending relative to the second curved body 1016. The plurality of extensions 5018 spaced (e.g., azimuthally spaced) from each other along a length (such as a curved length) of the second curved body 1016. The present disclosure contemplates that features of the absorptive masses 4015, 5015 (such as the openings 4018 and the extensions 5018) can increase a surface area of the outer faces of the absorptive masses 4015, 5015, which can facilitate activation of the process gases P1.

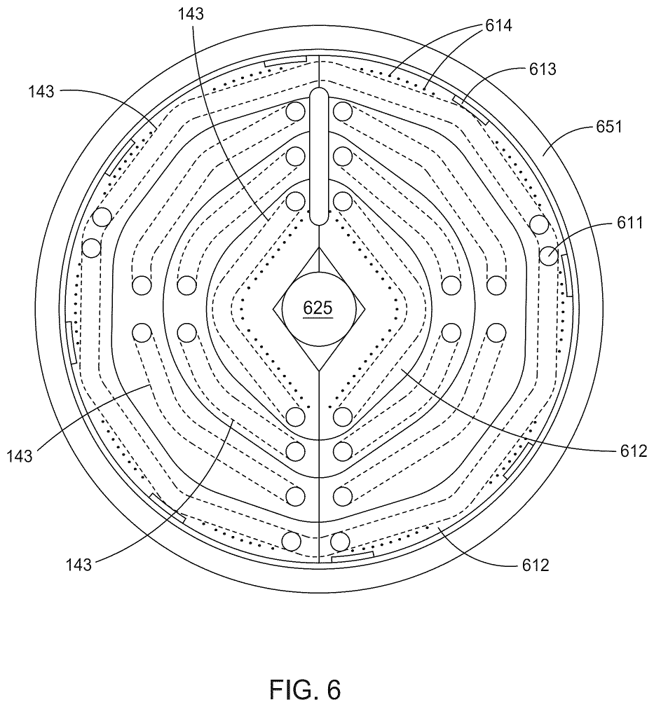

FIG. 6 is a schematic top view of the reflector 601 shown in FIG. 1A, according to one or more embodiments.

The one or more recessed surfaces 612 can be defined by a plurality of grooves formed in the reflector 601. The plurality of grooves are respectively configured to hold one or more horizontal heat sources 143 (such as linear heat sources) extending along the direction of the respective groove. The heat sources 143 are shown in ghost in FIG. 6 for visual clarity purposes. The plurality of grooves are arranged to form concentric rings. The concentric rings can be hexagonal in shape.

The one or more recessed surfaces 612 respectively include a set of first openings 611 having a first diameter, a set of second openings 614 having a second diameter smaller than the first diameter, and a set of slots 613 (e.g., elongated slots) having a length larger than the first diameter and the second diameter. The present disclosure contemplates that the second diameter can vary for the second openings 614. The first openings 611 allow an electrical connection and/or mechanical connection of the heat sources 143 to be disposed therethrough. A cooling fluid (such as air) can be flowed through the second openings 614 and/or the slots 613 to cool the lower plate 110, the reflector 601, and/or the heat sources 143. A slot 615 (e.g., an elongated slot) is formed in the reflector 601. The slot 615 can allow sensor device(s) (such as pyrometer(s)) to take measurements through the slot 615. In one or more embodiments, the slot 615 extends at least partially into at least one of the one or more recessed surfaces 612.

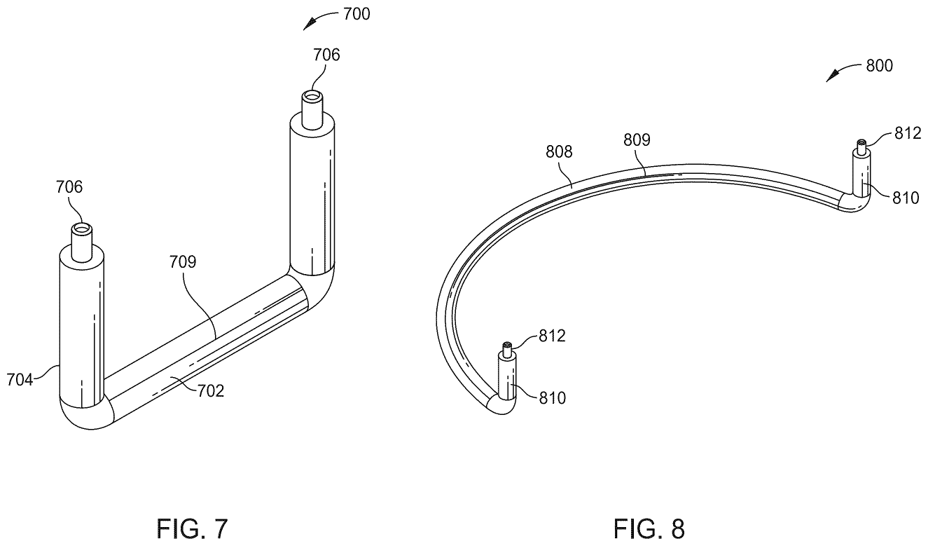

FIG. 7 is a schematic perspective view of a linear lamp 700 for use within the processing chamber 100 of FIG. 1, according to one or more embodiments. As an example the linear lamp 700 can be used as the upper heat sources 141 and/or the lower heat sources 143. The linear lamp 700 includes a linear bulb 702, one or more arms 704, and one or more electrical connections 706. In one or more embodiments, the linear lamps 700 are infrared (IR) halogen lamps. The linear bulb 702 is a cylindrical bulb with a filament 709 disposed therein. The linear bulb 702 is configured to emit a radiative energy, such as IR light, towards the substrate 102 when positioned within the processing chamber.

The one or more arms 704 extend from the linear bulb 702. As shown in FIG. 7, there are two arms 704 and one arm extends from each distal end of the linear bulb 702. The two arms 704 can extend in a direction perpendicular to the direction in which the linear bulb 702 extends. The present disclosure contemplates that the two arms 704 can extend obliquely relative to the linear bulb 702 to extend through an angled orientation of the first openings 511 shown in FIGS. 5 and 6. The two arms 704 can extend in the same direction or can be angled to extend in opposite directions. At the end of each of the arms 704 is an electrical connection 706. The electrical connection 706 is configured to be plugged into or coupled to a socket or other power source. The electrical connections 706 are electrically coupled to the filament 709 within the linear bulb 702 and enable the linear lamp 700 to be powered.

FIG. 8 is a schematic perspective view of a curved lamp 800 for use within the processing chamber 100 of FIG. 1, according to one or more embodiments.

The curved lamp 800 includes a curved bulb 808, one or more arms 810, and one or more electrical connections 812. The curved bulb 808 is a tubular bulb shaped to form at least a portion of a ring, such as an arcuate ring. The curved bulb 808 includes a filament 809 disposed therein. The curved bulb 808 is configured to emit a radiative energy towards the substrate 102 when positioned within the processing chamber.

The one or more arms 810 extend from the curved bulb 808. As shown in FIG. 8, there are two arms 810, and one arm extends from each distal end of the curved bulb 808. The arms 810 can extend orthogonally or obliquely to a plane of the curved bulb 808. The two arms 810 extend in a direction perpendicularly or obliquely to the direction in which the curved bulb 808 extends. The two arms 810 can extend in the same direction are can be angled to extend in opposite directions. The arms 810 extend through the first openings 511 of the reflector 401. At the end of each of the arms 810 is an electrical connection 812. The electrical connection 812 is configured to be plugged into or coupled to a socket or other power source. The electrical connections 812 are electrically coupled to a filament 809 within the curved bulb 808 and enable the curved lamp 800b to be powered.

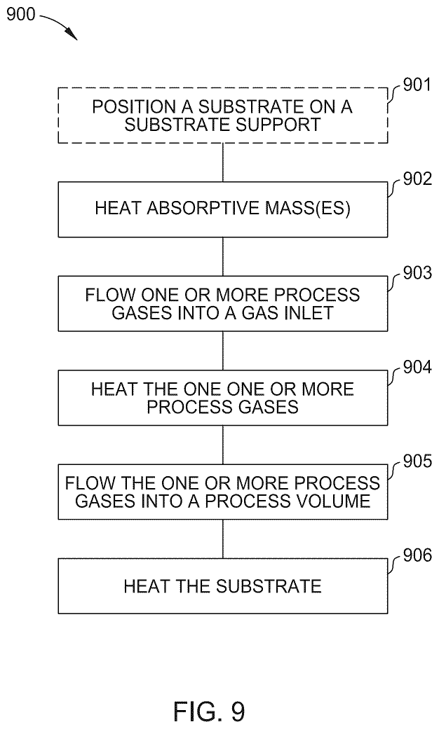

FIG. 9 is a schematic block diagram view of a method 900 of substrate processing, according to one or more embodiments. In one or more embodiments, the method 900 is performed using one or more components of the processing chamber 1000 described herein.

Optional operation 901 of method 900 includes positioning a substrate on a substrate support in a processing volume of a processing chamber. In one or more embodiments, the positioning includes moving a substrate support and/or a plurality of lift pins relative to each other to land the substrate on the substrate support.

Operation 902 of the method 900 includes heating one or more absorptive masses disposed in a gas inlet path of the processing chamber. The heating includes emitting an electromagnetic radiation to the one or more absorptive masses such that the one or more absorptive masses absorb the electromagnetic radiation, which causes the temperature of the absorptive mass to increase. In one or more embodiments, the heating of the one or more absorptive masses includes adjusting a heating power of one or more heat sources. The adjusting can include adjusting a non-zero value of the heating power during heating, and/or can include turning the heating power on and off intermittently. For example, the heating power of one or more heat sources can be turned on and/or turned off for a respective period of time that is adjustable, which can adjust the heating of the one or more absorptive masses.

Operation 903 of the method 900 includes flowing one or more process gases from one or more process gas sources and over the one or more absorptive masses to pre-heat the one or more process gases. The one or more process gases flow toward the one or more absorptive masses at a first temperature. The one or more process gases can include one or more reactive gases (such as one or more of silicon-containing, phosphorus-containing, and/or germanium-containing gases, one or more carrier gases (such as one or more of nitrogen (N2) and/or hydrogen (H2)), and/or one or more etchant gases (such as one or more of hydrogen and/or chlorine (such as hydrochloric acid (HCl)).

Operation 904 of the method 900 includes heating the one or more process gases of operation 903. The one or more process gases are heated by flowing the one or more process gases over the one or more absorptive masses. In one or more embodiments, the one or more process gases are heated to a second temperature higher than the first temperature. The second temperature can be lower than the first temperature. In one or more embodiments, the second temperature is within a range of 50 degrees Celsius to 500 degrees Celsius, such as 100 degrees Celsius to 450 degrees Celsius. In one or more embodiments, the second temperature is within a range of 600 degrees Celsius to 1,200 degrees Celsius. The first temperature and/or the second temperature can vary depending, for example, on process recipes.

Operation 905 of the method 900 includes flowing the one or more process gases over the substrate to process the substrate. The one or more process gases flow from the absorptive mass and into the processing volume. The one or more process gases can flow across the substrate while within the processing volume.

Operation 906 includes heating the substrate to a substrate temperature. In one or more embodiments, the substrate temperature is less than 550 degrees Celsius, such as less than 500 degrees Celsius. In one or more embodiments, the substrate temperature is 450 degrees Celsius or less, such as 400 degrees Celsius or less, for example 350 degrees Celsius or less. In one or more embodiments, the substrate temperature is 600 degrees Celsius or higher, such as 1,000 degrees Celsius or higher. Other substrate temperatures are contemplated.

Benefits of the present disclosure include activation of one or more process gases for processing, increased activation path lengths, increased deposition efficiency, and decreased maintenance and decreased cost. The present disclosure contemplates that the subject matter can be used for gas activation in relation to relatively low temperature processing and/or relatively high temperature processing. Benefits also include enhanced dopant concentrations and distributions, enhanced device performance, adjustability of processing and adjustability of activation, such as based on varying gas compositions and/or gas flow rates. Such benefits can be facilitated in a manner that is simple and modular, involving reduced changes to chamber design and reduced changes to electrical lines.

It is contemplated that one or more aspects disclosed herein may be combined. As an example, one or more aspects, features, components, operations and/or properties of the processing chamber 1000, the absorptive mass 1015, the liner(s) 1020, 1030, the heat sources 141, 143, the absorptive masses 3015, the absorptive mass 4015, the absorptive mass 5015, the reflector 601, the linear lamp 700, the curved lamp 800, and/or the method 900 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A processing chamber, comprising:
a chamber body at least partially defining an internal volume, the chamber body comprising one or more gas inlet openings;
a substrate support disposed in the internal volume;
one or more heat sources;
a liner disposed at least partially about the internal volume; and
an absorptive mass supported at least partially by the liner between the one or more gas inlet openings and the substrate support.

2. The processing chamber of claim 1, wherein the liner comprises an opening formed in an outer face of the liner, and the absorptive mass is disposed at least partially in the opening of the liner.

3. The processing chamber of claim 2, wherein the liner further comprises a first shoulder on a first side of the opening and a second shoulder on a second side of the opening.

4. The processing chamber of claim 1, wherein the absorptive mass is formed of an opaque material.

5. The processing chamber of claim 4, wherein the absorptive mass has an emissivity of 0.80 or higher at a processing temperature.

6. The processing chamber of claim 1, wherein the absorptive mass is formed of silicon carbide, and a transparent section of the liner that supports the absorptive mass is formed of a transparent material.

7. The processing chamber of claim 6, wherein the liner further comprises an opaque section disposed azimuthally outside of the transparent section, and the opaque section is formed of an opaque material.

8. A chamber kit, comprising:
a liner comprising a first curved body and an opening formed in an outer face of the first curved body;
an absorptive mass comprising a second curved body sized and shaped for disposition at least partially in the opening of the liner, the absorptive mass formed of an opaque material.

9. The chamber kit of claim 8, wherein the second curved body comprises a plurality of openings formed in an outer face of the second curved body, the plurality of openings spaced from each other along a length of the second curved body.

10. The chamber kit of claim 8, wherein the absorptive mass comprises a plurality of extensions extending relative to the second curved body, the plurality of extensions spaced from each other along a length of the second curved body.

11. The chamber kit of claim 8, wherein the second curved body has a cross-section having a width that is lesser than a height.

12. The chamber kit of claim 11, wherein the liner further comprises a first shoulder on a first side of the opening and a second shoulder on a second side of the opening.

13. The chamber kit of claim 12, wherein the height of the second curved body is larger than respective heights of the first shoulder and the second shoulder.

14. The chamber kit of claim 8, wherein the absorptive mass has an emissivity of 0.80 or higher at a processing temperature.

15. The chamber kit of claim 8, wherein the absorptive mass is formed of silicon carbide, and a transparent section of the liner is formed of a transparent material.

16. The chamber kit of claim 15, wherein the liner further comprises an opaque section disposed azimuthally outside of the transparent section, and the opaque section is formed of an opaque material.

17. A method of substrate processing, comprising:
heating an absorptive mass disposed in a gas inlet path of a processing chamber, the heating comprising:
emitting an electromagnetic radiation to the absorptive mass such that the absorptive mass absorbs the electromagnetic radiation;
heating a substrate in the processing chamber;
flowing one or more process gases over the absorptive mass to pre-heat the one or more process gases; and
flowing the one or more process gases over the substrate to process the substrate.

18. The method of claim 17, wherein one or more first zones of a plurality of heat sources emit the electromagnetic radiation to the absorptive mass, and one or more second zones of the plurality of heat sources emit electromagnetic radiation to the substrate.

19. The method of claim 18, wherein the one or more first zones are disposed radially outwardly of at least one of the one or more second zones.

20. The method of claim 19, wherein the heating of the absorptive mass comprises adjusting a heating power.
